(19) United States
(12) Patent Application Publication
(10) Pub. No.: US 2014/0124843 A1
(43) Pub. Date: May 8, 2014

(54) Photo Sensor

(71) Applicant: Chang Hun HAN, Icheon-si (KR)

(72) Inventor: Chang Hun HAN, Icheon-si (KR)

(21) Appl. No.: 13/763,397

(22) Filed: Feb. 8, 2013

(30) Foreign Application Priority Data
Nov. 5, 2012 (KR) 10-2012-0124221

(51) Int. Cl. H01L 27/146

(52) U.S. Cl. CPC H01L 27/14643
USPC 257/292

(57) ABSTRACT

Disclosed is a photo sensor including a first conductive type semiconductor substrate, a photodiode region in a light receiving region of the semiconductor substrate, a first transistor including a first gate, a first source region and a first drain region, the first transistor being adjacent to the photodiode region, and a light-absorption control layer in a first region of the photodiode region, the light-absorption control layer exposing a second region of the photodiode region, wherein the first region is spaced apart from the first source region, and the second region is another portion of the photodiode region contacting the first source region.

This application claims the benefit of Korean Patent Application No. 10-2012-0124221, filed on Nov. 5, 2012, which is incorporated herein by reference as if fully set forth herein.

### BACKGROUND OF THE INVENTION

1. Field of the Invention

The present invention relates to a photo sensor, and more particularly, to a sensor for photo mice.

2. Discussion of the Related Art

A photo sensor is a semiconductor device which performs sensing by converting light into an electric signal. The photo sensor can sense in a non-contact and non-destruction method at a high speed without providing noise to surroundings. Photoelectric conversion is classified into photoelectric, photoconductive, photovoltaic and pyroelectric effects.

The type of the photo sensor includes a single photo sensor, one-dimensional and two-dimensional photo sensors, a multi-photo sensor and the like. A semiconductor material is generally used as the photo sensor. The photo sensor may be classified depending on the wavelength range of light employed, such as infrared light or visible light.

An optical mouse sensor using infrared light is also a kind of photo sensor, and a unit pixel of the optical mouse sensor includes one photodiode and a plurality of transistors. An optical mouse sensor is classified into 3T, 4T and 5T-types, depending on the number of transistors.

### SUMMARY OF THE INVENTION

Accordingly, the present invention is directed to a photo sensor that substantially obviates one or more problems due to limitations and disadvantages of the related art.

It is one object of the present invention to provide a photo sensor that improves response speed.

To achieve these objects and other advantages, and in accordance with the purpose(s) of the invention, as embodied and broadly described herein, a photo sensor is provided, including a first conductive type semiconductor substrate; a photodiode region in a light receiving region of the semiconductor substrate; a first transistor including a first gate, a first source region and a first drain region, the first transistor being adjacent to the photodiode region; and a light-absorption control layer in a first region of the photodiode region, the light-absorption control layer exposing a second region of the photodiode region, wherein the first region is of the photodiode region spaced apart from the first source region, and the second region of the photodiode region contacts the first source region.

The first region may be a portion that extends within a first distance from peripheral boundaries of the photodiode region and is spaced by a second distance or more from the peripheral boundary that is the closest to the first source region. The first distance may be smaller than half of a width of the photodiode region, and the second distance may be equal to or larger than half of a length of the photodiode region.

A side of the light-absorption control layer that faces the first source region may have a curved surface.

The second region may be a portion of the photodiode region that extends within a first distance from the first source region, the first region may be a portion of the photodiode region excluding the second region, and the first distance may be equal to or larger than a distance from a vertex that is closest vertex among all vertices in the peripheral boundary to the first source region to the first source region.

The light receiving region of the photodiode region may include a first doping region having a first conductive type and a second doping region having a second conductive type, in this order from bottom to top.

A depth of a first lowermost surface of the first doping region may be different from depth of a second lowermost surface of the first doping region in the second region.

The light-absorption control layer may have a structure comprising a polysilicon-on-insulating film stack. The light-absorption control layer may further have a structure comprising a capacitor-on-insulating film stack, and the capacitor may include a lower polysilicon layer, a dielectric layer, and an upper polysilicon layer.

In accordance with another aspect of the present invention, a photo sensor is provided, including a semiconductor substrate having a first conductive type; a photodiode region in a light receiving region of the semiconductor substrate; a first transistor including a first gate, a first source region and a first drain region, the first transistor being adjacent to the photodiode region; and a light-absorption control layer in a first region of the photodiode region, the light-absorption control layer exposing a second region of the photodiode region, wherein the first region is spaced apart from the first source region, and the second region is adjacent to the first source region and excludes the first region, wherein a thickness of the light-absorption control layer decreases a first direction from a first peripheral boundary of the photodiode region that is farthest from the first source region toward a second peripheral boundary of the photodiode region that is closest to the first source region.

The first region may be a portion that extends within a first distance from the first peripheral boundary, and the second region may be a portion of the photodiode region excluding the first region. The first distance may be smaller than or equal to a length of the photodiode region and may be equal to or larger than half of the length.

The light receiving region of the photodiode region may include a first doping region having a first conductive type and a second doping region having a second conductive type in this order from bottom to top in the semiconductor substrate, and a depth of a first lowermost surface of the first doping region in the first region may decrease along the first direction.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and along with the description serve to explain the principle(s) of the invention. In the drawings:

FIG. 1 shows a layout of a unit pixel of a photo sensor according to one embodiment;

FIG. 2 is a cross-sectional view taken along the direction AB of the photo sensor shown in FIG. 1;

FIG. 3 is a plan view illustrating a photo sensor according to another embodiment;

FIG. 4 is a cross-sectional view taken along the direction CD of the photo sensor shown in FIG. 3;

FIG. 5 is a plan view illustrating a photo sensor according to another embodiment;

FIG. 6 is a cross-sectional view taken along the direction AB of the photo sensor shown in FIG. 5;

FIG. 7 is a cross-sectional view illustrating a photo sensor according to another embodiment; and

FIG. 8 shows an absorption coefficient and the penetration depth of a general silicon substrate as a function of the wavelength of light.

### DETAILED DESCRIPTION OF THE INVENTION

The above and other objects, features and other advantages of the present invention will be more clearly understood from the following detailed description taken in conjunction with the accompanying drawings. With regard to the description of various embodiments according to the present invention, it will be understood that, when one element such as a layer, a film, a region or a structure is referred to as being “on” or “under” another element such as a substrate, a layer, a film, a region, a pad or a pattern, the one element may be formed directly “on” or “under” the other element, or be formed indirectly “on” or “under” the other element with one or more intervening elements present therebetween. Further, “on” or “under” each element is described based on the drawings.

In the drawings, the thicknesses or sizes of respective layers are exaggerated, omitted or schematically illustrated for convenience and clarity of description. Therefore, the sizes of respective elements do not wholly reflect actual sizes thereof. Hereinafter, a photo sensor according to one or more embodiments of the present invention will be described in detail.

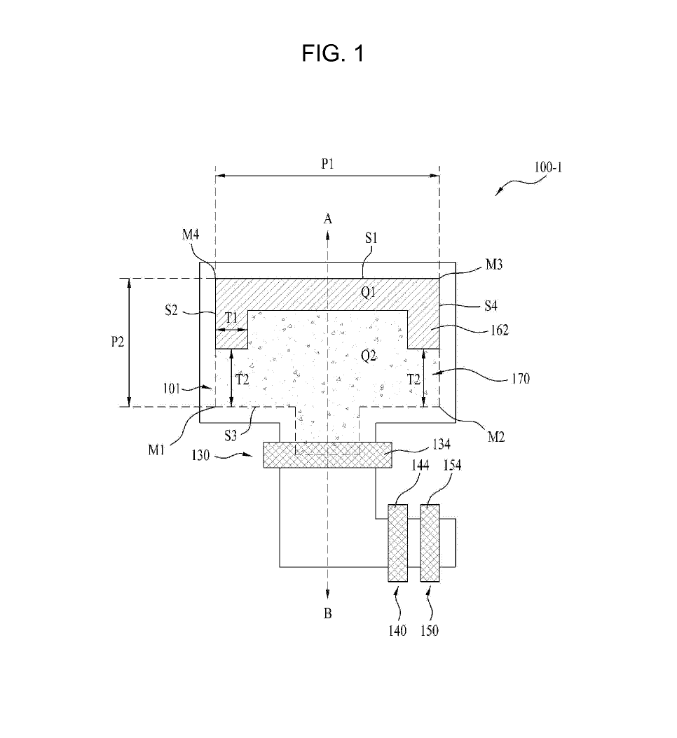

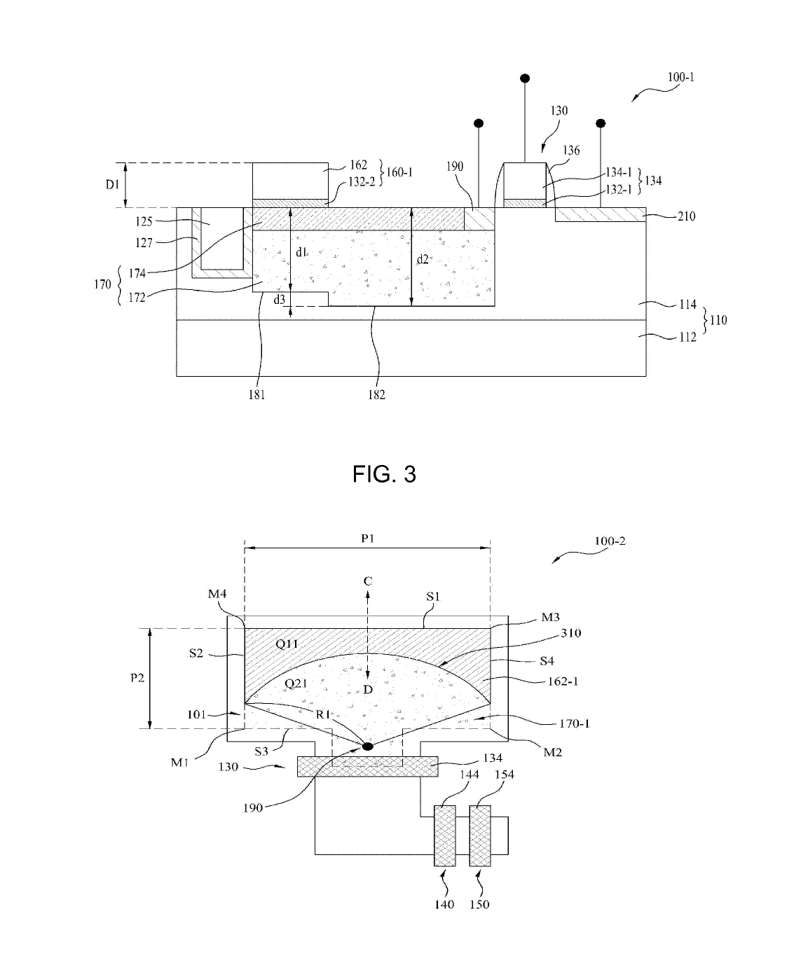

FIG. 1 shows a layout of a unit pixel of a photo sensor 100-1 according to an embodiment. FIG. 2 is a cross-sectional view taken along the direction AB of the photo sensor 100-1 shown in FIG. 1.

Referring to FIGS. 1 and 2, the photo sensor 100-1 includes one photodiode region 180 and three transistors 130, 140 and 150 in one unit pixel. The photo sensor 100-1 includes a semiconductor substrate 110, a device isolation film 125 formed in the semiconductor substrate 110, a photodiode region 170 including a first doping region 172 and a second doping region 174 formed in an epilayer 114, a third doping region 127 surrounding the surface of the device isolation film 125, between the device isolation film 125 and the photodiode region 170, first to third gates 134, 144 and 154 formed on the epilayer 114, and a light-absorption control layer 160-1 formed on the semiconductor substrate 110.

The semiconductor substrate 110 may include a silicon substrate 112 comprising or consisting essentially of a polycrystalline semiconductor (for example, silicon) containing a high concentration of a first conductive type (e.g., P++) impurity, and an epitaxial layer (e.g., epilayer) 114 containing a low concentration of a first conductive type (P−) impurity. The epitaxial layer 114 may be formed on a semiconductor substrate 110 using an epitaxial process. For example, the concentration of p-type impurities in the epilayer 114 may be lower than the concentration of p-type impurities in the semiconductor substrate 110.

The photodiode region 170 has a wide depletion region and a large depth through the low-concentration first conductive type epilayer 114. For this reason, collection of photocharges by a low-voltage photodiode and the photosensitivity of the device can be improved.

The device isolation film 125 is formed on or in the semiconductor substrate 110 to define an active region and an isolation region. For example, the device isolation film 125 may be formed in the epilayer 114 through a shallow trench isolation (STI) or local oxidation of silicon (LOCOS) process.

The first to third gates 134, 144 and 154 may be spaced apart from one another on the semiconductor substrate 110. For example, a first gate 134 may be formed in the active region of the semiconductor substrate 110 at one side of the device isolation film 125. A second gate 144 may be formed in the active region of the semiconductor substrate 110 at one side of the first gate 134. A third gate 154 may be formed in the active region of the semiconductor substrate 110 at one side of the second gate 144. Generally, the first to third gates 134, 144 and 154 are formed simultaneously. The first gate 134 may be a reset gate, the second gate 144 may be a drive gate, and the third gate 154 may be a select gate.

A spacer 136 may be formed on sidewalls of each of the first to third gates 134, 144 and 154.

Source and drain regions doped with impurity ions may be formed in the active region of the semiconductor substrate 110 at opposite sides of the first to third gates 134, 144 and 154. For example, a high concentration of second conductive type (for example, n-type) impurities may be formed (e.g., by ion implantation) in the first source region 190 and the first drain region 210 of the semiconductor substrate 110 adjacent to opposite sides of the first gate 134. Generally, source and drain regions are simultaneously formed on opposite sides of the gates 144 and 154.

Each of the first to third gates 134, 144 and 154 may include a first insulating film 132-1 and a gate electrode 134-1. The first insulating film 132-1 and the gate electrode 134-1 may be formed or stacked in this order on the semiconductor substrate 110. The first insulating film 132-1 may comprise or consist essentially of an oxide film (e.g., silicon oxide, hafnium oxide, etc.) and/or a nitride film (e.g., silicon nitride). The gate electrode 134-1 may comprise or consist essentially of polysilicon.

The photodiode region 170 may be formed in a light receiving region (P1×P2) of the semiconductor substrate 110 between the device isolation film 125 and the first gate 134. The light receiving region (P1×P2) may be an active region of the semiconductor substrate 110 in which the photodiode region 170 is formed in order to sense light. For example, the light receiving region (P1×P2) has a width of P1 and a length of P2.

The photodiode region 170 may comprise a light receiving region of the semiconductor substrate 110 (P1×P2) doped with an impurity. The photodiode region 170 may include a first doping region 172 and a second doping region 174, in this order from the bottom to the top in the light receiving region of the semiconductor substrate 110 (P1×P2).

The first doping region 172 may be a region doped with a second conductive type impurity (for example, n-type impurity) in the light receiving region (P1×P2) of the semiconductor substrate 110. The first doping region 172 may form a pn-junction with the first conductive type semiconductor substrate 110.

The second doping region 174 may be formed on the surface of the semiconductor substrate 110 between the device isolation film 125 and the first source region 190. The second doping region 174 may be disposed in an upper part of the first doping region 170, a lower surface of the second doping region 174 may contact an upper surface of the first doping region 172, and one side of the second doping region 174 may contact the first source region 190. For example, the second doping region 174 may be formed in the epilayer 112 between the surface of the semiconductor substrate 110 and the upper surface of the second doping region 174. The second doping region 174 may isolate the upper surface of the first doping region 170 from the surface of the semiconductor substrate 110.

The second doping region 174 may be doped with a high concentration of the first conductive type (for example, p+ type) impurity, to prevent a dangling bond of the photodiode region 170 and/or inhibit movement of dark current along the surface of the photodiode region 170. In another embodiment, the second doping region 174, which functions to inhibit the dark current, may be omitted and in this case, the photodiode region 170 may be or comprise a first doping region 172, and the first doping region 172 may extend to the surface of the epilayer 114.

A p-type epilayer 114 may be grown on the semiconductor substrate 110 and a photodiode region 170 formed in p-type epilayer 114 at one side of the first gate 134, in this order, and a pnp junction structure including the p-type epilayer 114, the first doping region 172 and the second doping region 174 may result.

The third doping region 127 may be formed on semiconductor substrate 110, for example, in the active region of the epilayer 114 adjacent to the interface with the device isolation film 125. The third doping region 127 may contact the device isolation film 125 and surround the device isolation film 125.

A part of the third doping region 127 may be between the device isolation film 125 and the photodiode region 170, and may be doped with the first conductive type impurity. Since the third doping region 127 is doped with the first conductive type impurity, the first doping region 172 doped with the second conductive type impurity may be isolated from the device isolation film 125. The third doping region 127 thereby blocks movement of leakage current from the first doping region 172 along the interface with the isolation film, and thereby prevents crosstalk between adjacent unit pixels.

The light-absorption control layer 160-1 may be formed in or on one portion or subregion of the photodiode region 170 between the device isolation film 125 and the first gate 134. The light-absorption control layer 160-1 may expose another portion (e.g., the remainder) of the photodiode region 170.

The light-absorption control layer 160-1 may be in a first region Q1 of the photodiode region 170 and expose a second region Q2 of the photodiode region 170. The first region Q1 may be a portion of the photodiode region 170 spaced apart from the first source region 190 and/or the first gate 134, and the second region Q2 may be another portion of the photodiode region 170 which is between the first region Q1 and the first source region 190, and contacts the first source region 190.

For example, the first region Q1 extends within a first distance T1 from peripheral boundaries or edges S1 to S4 (cumulatively, “the peripheral boundary”) of the photodiode region 170 and is a second distance T2 or more from peripheral boundary or edge S3, which is the closest to the first source region 190. The first distance T1 may be smaller than half the width P1 of the photodiode region 170 (T1<P1/2). The second distance T2 may be equal to or smaller than half the length P2 of the photodiode region 170. Peripheral boundaries or edges S1 to S4 of the photodiode region 170 may be boundary sides forming the boundary between the semiconductor substrate 110 and the photodiode region 170.

The second region Q2 may be a portion of the photodiode region 170 excluding the first region Q1. The first region Q1 and the second region Q2 shown in FIG. 1 may include female and male coupling, but the present invention is not limited thereto. For example, the first region Q1 may have a U-shape or a C-shape, while the second region Q2 may have a complementary T-shape.

The light-absorption control layer 160-1 may include a second insulating film 132-2 and a polysilicon layer 162. The second insulating film 132-2 and the polysilicon layer 162 may be stacked in this order on the photodiode region 170. In an example excluding the second doping region 174, the light-absorption control layer 160-1 may have a structure in which the second insulating film 132-2 and the polysilicon layer 162 are laminated in this order on the first doping region 172.

A second depth d2 from the surface of the epilayer 114 to the second lowermost surface 182 of the first doping region 172 under the second region Q2 may be 0.5 to 5 um, and a thickness of the light-absorption control layer 160-1 may be 0.2 um to 1 um.

The light-absorption control layer 160-1 may control a depth at which light (for example, infrared light) is absorbed in the first region Q1 (and optionally, the second region Q2) of the photodiode region 170, a depth of photoelectric effect, and a depth of a pn-junction plane (e.g., at 181). A first depth d1 from the surface of the epilayer 114 to the first lowermost surface 181 of the first doping region 172 in or under the first region Q1 may be different from a second depth d2 from the surface of the epilayer 114 to a second lowermost surface 182 of the first doping region 172 in or under the second region Q2 (d1≠d2). For example, the first depth d1 may be lower than the second depth d2 (d1<d2), and a difference d3 between the first depth d1 and the second depth d2 may be 0.2 um to 1 um.

The light-absorption control layer 160-1 may be used as an ion injection mask for formation of the first doping region 172. For this reason, the first lowermost surface 181 is lower than the second lowermost surface 182 to an extent corresponding to the thickness of the light-absorption control layer 160-1.

The first lowermost surface 181 may be a first pn-junction surface of the photodiode region 170 in the first region Q1, and the second lowermost surface 182 may be a second pn junction surface of the photodiode region 170 in the second region Q2. As a result, the depth d1 of the first pn junction surface 181 of the photodiode region 170 may be less than the depth d2 of the second pn-junction surface 182.

The first conductive type may be p-type, and the p-type impurity may be or comprise boron (B), indium (In), or gallium (Ga). The second conductive type may be n-type, and the n-type impurity may be or comprise arsenic (As), phosphorus (P), or antimony (Sb). In another embodiment, the first conductive type may be n-type, and the second conductive type may be p-type.

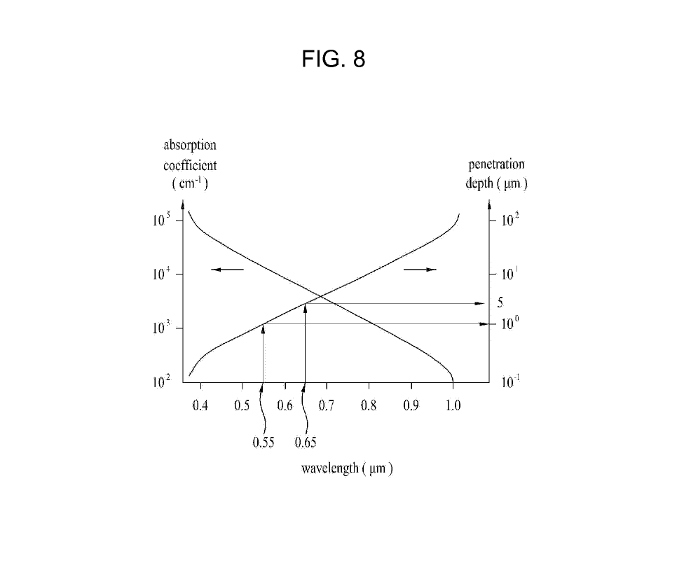

FIG. 8 shows an absorption coefficient and a penetration depth of a general silicon substrate as a function of the wavelength of light. The X axis represents the wavelength of light, the left-hand Y axis represents the absorption coefficient of the substrate, and the right-hand Y axis represents the penetration depth.

Referring to FIG. 8, as the wavelength of light increases, the depth at which light is absorbed in the silicon substrate increases. For example, as the wavelength of received light increases from 0.55 um to 0.65 um, the depth at which light is absorbed therein increases from about 1 um to about 5 um.

Since a photo sensor sensing infrared light has a larger absorption depth than that of a photo sensor sensing visible light, the depth of the region where photoelectric effects occur may increase. Accordingly, a pn junction depth of the photodiode region of a photo sensor sensing infrared light should be greater than that of a sensor sensing visible light.

For example, the photo sensor sensing infrared light exhibits a photoelectric effect at a depth of 2 um or more. As the depth at which the photoelectric effect occurs increases in the photo sensor sensing infrared light, a distance from the region where the photoelectric effect occurs to the reset transistor may increase. This increase in distance may increase the time for signal carriers (e.g., electrons) generated by photoelectric effect to transfer or migrate to the reset transistor, thus causing a decrease in the response speed of the photo sensor.

In this embodiment, the photo sensor is, for example, a sensor sensing infrared light with a wavelength of 0.65 um to um. The embodiment includes the light-absorption control layer 160-1 and the first region Q1 of the photodiode region 170, which is relatively far from the first gate 134 of the reset transistor 130 or the first source region 190, and which has a relatively small light penetration depth and which reduces the depth at which the photoelectric effect occurs, as compared to the second region Q2. Also, the depth of the pn-junction of the photodiode region 170 in or under the first region Q1 may be smaller than the depth of the pn-junction of the photodiode region 170 in or under the second region Q2. For this reason, the embodiment improves the response speed of the photo sensor.

Since the photo sensor of the embodiment absorbs infrared light, it can reduce the absorption depth of signal carriers (e.g., electrons) generated in a region having a depth of 2 um or more in a vertical direction through the light-absorption control layer 160-1 and improve the response speed.

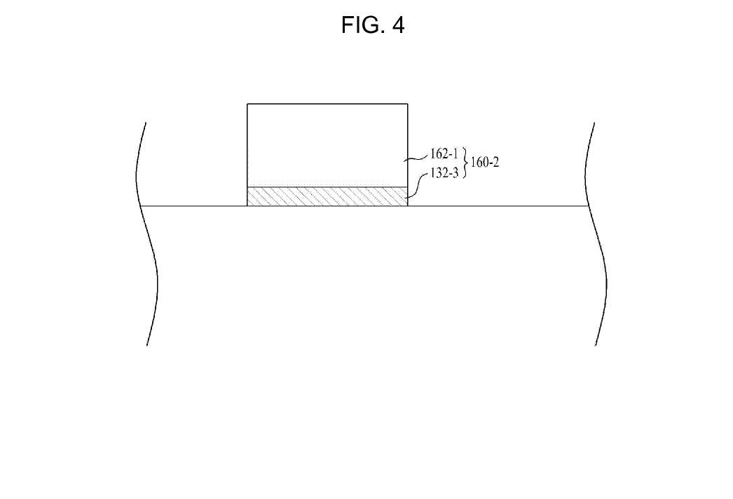

FIG. 3 is a plan view illustrating a photo sensor 100-2 according to another embodiment. FIG. 4 is a cross-sectional view taken along the direction CD of the photo sensor 100-2 shown in FIG. 3. The same reference numerals in FIGS. 3 and 4 represent the same configurations and the contents described above with regard to FIGS. 1 and 2, and the corresponding descriptions thereof may be omitted or described in brief.

Referring to FIG. 3, the light-absorption control layer 160-2 of the embodiment 100-2 shown in FIG. 3 may be disposed in a first region Q11 of the photodiode region 170-1 and may expose a second region Q21 of the photodiode region 170-1. The second region Q21 may extend within a first distance R1 from the first source region 190, and the first region Q11 may be a region of the photodiode region 170-1 excluding the second region Q21. The first distance R1 may be equal to or larger than a distance from the vertices M1 and M2, which are the closest vertices to the first source region 190 among the vertices M1 to M4 along the peripheral boundary S1 to S4 to the first source region 190.

A side or edge 310 of the light-absorption control layer 160-2 that faces the first source region 190 may have a curved surface, and a distance from the side or edge 310 to the first source region 190 may be uniform. The light-absorption control layer 160-2 may include a second insulating film 132-3 and a polysilicon layer 162-1. The second insulating film 132-3 and the polysilicon layer 162-1 may be stacked in this order on the photodiode region 170.

The photo sensor 100-2 according to the embodiment can secure reliability and uniformity in improvement of the response speed, since a boundary line between the first region Q11 and the second region Q21 is a predetermined distance R1 from the first source region 190.

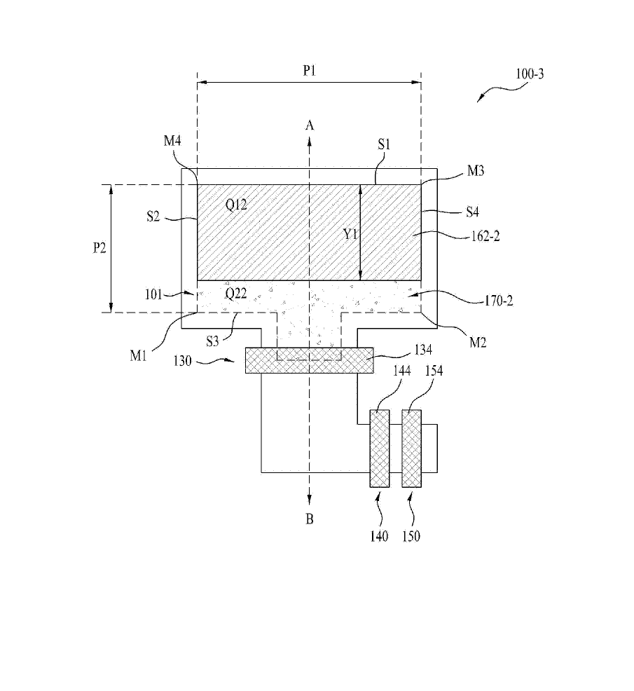

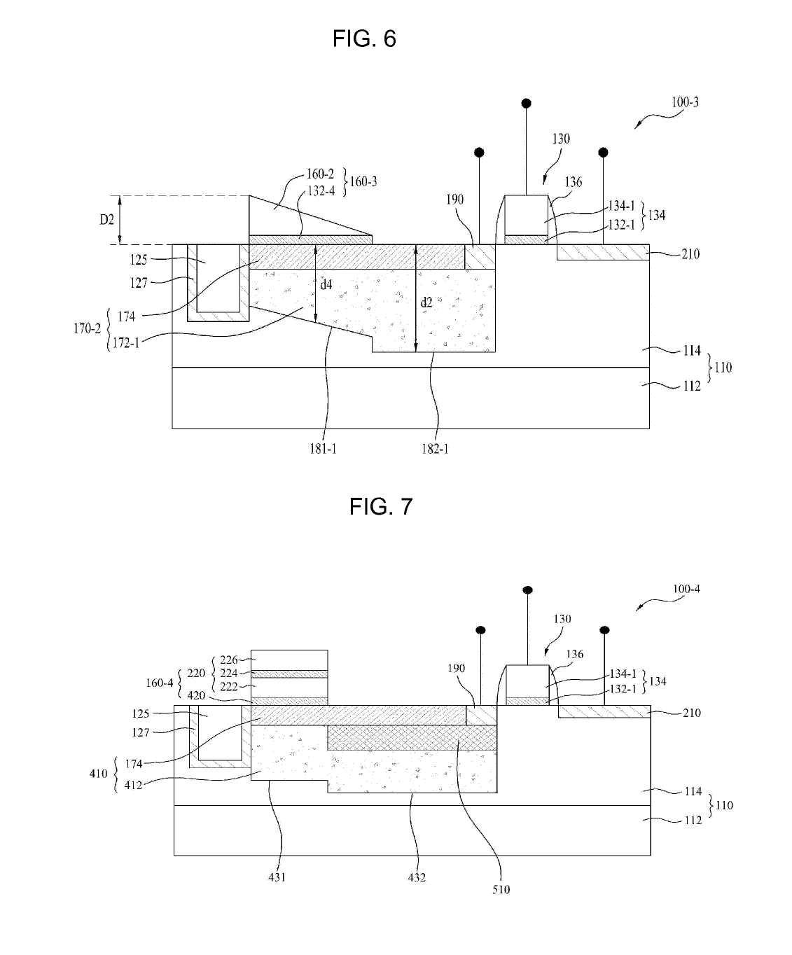

FIG. 5 is a plan view illustrating a photo sensor 100-3 according to another embodiment. FIG. 6 is a sectional view taken along the direction AB of the photo sensor 100-3 shown in FIG. 5. The same reference numerals in FIGS. 5 and 6 represent the same structures and/or configurations as in FIGS. 1-4, and the corresponding contents described above may be omitted or described in brief.

Referring to FIGS. 5 and 6, the light-absorption control layer 160-3 of the embodiment 100-3 may be disposed in a first region Q12 of the photodiode region 170-2, and may expose a second region Q22 of the photodiode region 170-2.

The first region Q12 may extend within a first distance Y1 from a first peripheral boundary or edge S1 of the photodiode region 170-2 that is farthest from the first source region 190, and the second region Q22 may be a portion of the photodiode region 170-2 excluding the first region Q12. The first distance Y1 may be less than or equal to a length P2 of the photodiode region 170-2, and may be half or more of the length P2.

A thickness D2 of the light-absorption control layer 160-3 may decrease from a first peripheral boundary or edge S1 of the photodiode region 170-2 toward a second peripheral boundary or edge S3 (hereinafter referred to as the “first direction”). The second peripheral boundary or edge S3 may be the peripheral edge or boundary of the photodiode region 170-2 which is the closest to the first source region 190. A thickness D2 of the light-absorption control layer 160-3 may linearly decrease along the first direction, but the present invention is not limited thereto. In another embodiment, the thickness D2 may decrease non-linearly or stepwise.

A first depth d4 from the surface of the epilayer 114 to a first lowermost surface 181-1 of the first doping region 172-1 in the first region Q12 may increase along the first direction. The first depth d4 may be less than a second depth d2 from the epilayer 114 to a second lowermost surface 182-1 of the first doping region 172-1 in the second region Q22.

When the first distance Y1 is equivalent to the length P2 of the photodiode region 170-2, the first region Q12 corresponds to the entirety of the photodiode region 170-2, and the light-absorption control layer 160-3 may be in the entirety of the photodiode region 170-2. As the thickness of the light-absorption control layer 160-3 decreases along the first direction, the depth d4 of the first lowermost surface 180-1 of the first doping region 172-1 may increase along the first direction.

FIG. 7 is a cross-sectional view illustrating a photo sensor 100-4 according to another embodiment. The same reference numerals in FIG. 7 represent the same structures and/or configurations as in FIGS. 1-6, and the corresponding contents described above may be omitted or described in brief.

Referring to FIG. 7, the light-absorption control layer 160-4 of the photo sensor 100-4 may be disposed in a first region of the photodiode region 410, and may expose a second region of the photodiode region 410. The photodiode region 410 may be any one of photodiode regions 170, 170-1, and 170-2 shown in FIGS. 1, 3, and 5, the first region of the photodiode region 410 may be any one of the first regions Q1, Q11 and Q12, and the second region of the photodiode region 410 may be any one of the second regions Q2, Q21 and Q22. Also, the first lowermost surface 431 of the first doping region 412 may be the first lowermost surface of the first doping region in the photodiode regions 170, 170-1 and 170-2, and the second lowermost surface 432 of the first doping region 412 may be the second lowermost surface of the first doping region in the photodiode regions 170, 170-1 and 170-2.

The light-absorption control layer 160-4 may include a second insulating film 420 and a capacitor 220. Alternatively, the light-absorption control layer 160-4 may include a second insulating film 420, a second polysilicon layer 222, a dielectric layer 224, and a third polysilicon layer 226, as the second and third polysilicon layers 222 and 226 may not be electrically connected to other structures. The second insulating film 420 may be disposed in a second region of the photodiode region 410 and may be any one of the second insulating films 132-2, 132-3 and 132-4 shown in FIGS. 2, 4 and 6. The capacitor 220 may be disposed on the second insulating film 420 and include a lower polysilicon layer 222, a capacitor dielectric layer 224 and an upper polysilicon layer 226. The lower polysilicon layer 222, the capacitor dielectric layer 224, and the upper polysilicon layer 226 may be stacked in this order on the second insulating film 420.

The light-absorption control layer 160-4 can control a light absorption depth (for example, an absorption depth of infrared light), and serve as a capacitor. Also, since the lower polysilicon layer 222, the capacitor dielectric layer 224, and the upper polysilicon layer 226 are stacked, the thickness of the light-absorption control layer 160-4 is generally greater than the thickness of the light-absorption control layer 160-1 of the first the embodiment 100-1, thereby further decreasing the penetration depth and enhancing the response speed.

The photo sensor 100-4 may further include a fourth doping region 510 having the second conductive type in the epilayer 114, between the first doping region 412 and the second doping region 174. The fourth doping region 510 may be in or under the second region of the photodiode region 410. Also, the fourth doping region 510 may be under the first source region 190. An upper surface of the fourth doping region 510 may contact a part of the lower surface of the second doping region 174 and a lower surface of the first source region 190. A lower surface of the fourth doping region 510 may contact an upper surface of the first doping region 412. The upper surface of the first doping region 412 may contact the lower surface of the second doping region 174 in the first region of the photodiode region 410 and the lower surface of the fourth doping region 510 in the second region of the photodiode region 410.

The second conductive type impurities in the first source region 190, the fourth doping region 510, and the first doping region 412 may be different. For example, the concentration of second conductive type impurities increases from the first source region 190 to the fourth doping region 510 and the first doping region 412 in order. The difference in concentration of first conductive type impurity between the first source region 190, the fourth doping region 510, and the first doping region 412 may result in generation of an electric field. The electric field enables signal carriers (e.g., electrons) to be transferred to the first drain region 210 of the first transistor 130, thus improving the response speed of the photo sensor 100-4.

Embodiments according to the present invention provide photo sensors that can improve response speed.

Particular features, structures, or characteristics described in connection with an embodiment are included in at least one embodiment of the present invention, but not necessarily in all embodiments. Furthermore, the particular features, structures, or characteristics of any specific embodiment of the present invention may be combined in any suitable manner with one or more other embodiments or features, structures, or characteristics of such embodiments, and may be changed by those skilled in the art to which the embodiments pertain.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A photo sensor comprising:
a semiconductor substrate having a first conductive type;
a photodiode region in a light receiving region of the semiconductor substrate;
a first transistor including a first gate, a first source region and a first drain region, the first transistor being adjacent to the photodiode region; and
a light-absorption control layer in a first region of the photodiode region, the light-absorption control layer exposing a second region of the photodiode region,
wherein the first region is spaced apart from the first source region, and the second region is another portion of the photodiode region contacting the first source region.

2. The photo sensor according to claim 1, wherein the first region extends within a first distance from a peripheral edge or boundary of the photodiode region and is a second distance or more from a peripheral edge or boundary that is closest to the first source region.

3. The photo sensor according to claim 2, wherein the first distance is smaller than half of a width of the photodiode region, and the second distance is equal to or larger than half of a length of the photodiode region.

4. The photo sensor according to claim 1, wherein a side or edge of the light-absorption control layer that faces the first source region has a curved surface.

5. The photo sensor according to claim 4, wherein the second region of the photodiode region extends within a first distance from the first source region, the first region of the photodiode region excludes the second region, and the first distance is equal to or larger than a distance from a peripheral boundary vertex that is closest to the first source region.

6. The photo sensor according to claim 1, wherein the light receiving region of the photodiode region comprises a first doping region having a first conductive type, and a second doping region having a second conductive type, in order from bottom to top.

7. The photo sensor according to claim 6, wherein a depth of a first lowermost surface of the first doping region in the first region is different from a depth of a second lowermost surface of the first doping region in the second region.

8. The photo sensor according to claim 1, wherein the light-absorption control layer has a polysilicon-on-insulating film stacked structure.

9. The photo sensor according to claim 1, wherein the light-absorption control layer has a capacitor-on-insulating film stacked structure, and the capacitor comprises a lower polysilicon layer, a dielectric layer and an upper polysilicon layer.

10. The photo sensor according to claim 1, wherein the light-absorption control layer has a stacked structure comprising an insulating film, a lower polysilicon layer, a dielectric layer and an upper polysilicon layer.

11. A photo sensor comprising:
a semiconductor substrate having a first conductive type;
a photodiode region in a light receiving region of the semiconductor substrate;
a first transistor including a first gate, a first source region and a first drain region, the first transistor being adjacent to the photodiode region; and
a light-absorption control layer in a first region of the photodiode region, the light-absorption control layer exposing a second region of the photodiode region, wherein the first region is spaced apart from the first source region, and the second region is adjacent to the first source region, and the second region excluding the first region,
wherein a thickness of the light-absorption control layer decreases along a first direction from a first peripheral boundary or edge of the photodiode region that is the farthest from the first source region toward a second peripheral boundary or edge of the photodiode region that is closest to the first source region.

12. The photo sensor according to claim 11, wherein the first region extends within a first distance from the first peripheral boundary or edge, and the second region excludes the first region.

13. The photo sensor according to claim 12, wherein the first distance is smaller than or equal to a length of the photodiode region, and equal to or larger than half of the length of the photodiode region.

14. The photo sensor according to claim 12, wherein the light receiving region comprises a first doping region having a first conductive type and a second doping region having a second conductive type in order from bottom to top in the semiconductor substrate, and
a depth of a first lowermost surface of the first doping region in the first region decreases along the first direction.
